(19) United States
(12) Patent Application Publication
(10) Pub. No.: US 2011/0308582 A1
(43) Pub. Date: Dec. 22, 2011

(54) PHOTOELECTRIC CONVERSION DEVICE AND MANUFACTURNING METHOD THEREOF

(75) Inventors: Riho Kataishi, Atsugi (JP); Jiro Nishida, Atsugi (JP); Kazutaka Kuriki, Ebina (JP)

(73) Assignee: SEMICONDUCTOR ENERGY LABORATORY CO., LTD., Atsugi-shi (JP)

(21) Appl. No.: 13/159,919

(22) Filed: Jun. 14, 2011

(30) Foreign Application Priority Data
Jun. 18, 2010 (JP) 2010-139999

(51) Int. Cl. H01L 31/02; H01L 31/18

(52) U.S. Cl. 136/252; 438/57; 257/E31.001

(57) ABSTRACT

A photoelectric conversion device with a novel anti-reflection structure is provided. An uneven structure is formed on a surface of a semiconductor by growth of the same or different kind of semiconductor instead of forming an anti-reflection structure by etching a surface of a semiconductor substrate or a semiconductor film. For example, a semiconductor layer including a plurality of projections is provided for a light incident plane side of the photoelectric conversion device, thereby considerably reducing surface reflection. Such a structure can be formed by a vapor deposition method; therefore, the contamination of the semiconductor is not caused.

### BACKGROUND OF THE INVENTION

1. Field of the Invention

The present invention relates to a photoelectric conversion device and a method for manufacturing the same.

2. Description of the Related Art

Recently, a photoelectric conversion device, which is a power generation means that generates power without carbon dioxide emissions, has attracted attention as a countermeasure against global warming. A solar cell for supplying residential power or the like, which generates power from sunlight outdoors, is known as a typical example thereof. For such a solar cell, a crystalline silicon solar cell using single crystal silicon or polycrystalline silicon is mainly used.

An uneven structure is provided on a surface of a solar cell using a single crystal silicon substrate or a polycrystalline silicon substrate in order to reduce surface reflection. The uneven structure provided on the surface of the silicon substrate is formed by etching the silicon substrate with an alkaline solution such as NaOH. The etching rate by the alkaline solution varies depending on a crystal plane orientation of silicon. Therefore, when a silicon substrate with a (100) plane is used for example, a pyramidal uneven structure is formed.

Although the above-described uneven structure can reduce surface reflection of the solar cell, the alkaline solution used for etching causes contamination of the silicon semiconductor. In addition, since etching characteristics considerably vary depending on the concentration or temperature of the alkaline solution, it is difficult to form the uneven structure on the surface of the silicon substrate with high reproducibility. For the difficulty, a combination method of a laser processing technique and chemical etching is disclosed (for example, see Patent Document 1).

On the other hand, in a solar cell whose photoelectric conversion layer is formed using a semiconductor thin film of silicon or the like, it is difficult to form an uneven structure on a surface of the silicon thin film by the above-described etching using alkaline solution.

### REFERENCE

### Patent Document

### [Patent Document 1]

Japanese Published Patent Application No. 2003-258285

### SUMMARY OF THE INVENTION

In any case, the method in which the silicon substrate itself is etched to form the uneven structure on the surface of the silicon substrate is not favorable because the method has a problem in controllability of the uneven shape and affects the characteristics of the solar cell. In addition, since the alkaline solution and a large amount of water for cleaning are needed for etching of the silicon substrate and it is necessary to pay attention to the contamination of the silicon substrate, the method is also not favorable in terms of productivity.

Thus, an object of an embodiment of the present invention is to provide a photoelectric conversion device having a novel anti-reflection structure.

One feature of an embodiment of the present invention is to form an uneven structure on a surface of a semiconductor by growth of the same or different kind of semiconductor instead of forming an anti-reflection structure by etching a surface of a semiconductor substrate or a semiconductor film.

For example, a semiconductor layer including a plurality of projections is provided on a light incident plane side of a photoelectric conversion device, thereby considerably reducing surface reflection. Such a structure can be formed by a vapor deposition method; therefore, the contamination of the semiconductor is not caused.

With the use of a vapor deposition method, a semiconductor layer including a plurality of whiskers can be grown, whereby the anti-reflection structure of the photoelectric conversion device can be formed.

An embodiment of the present invention is a photoelectric conversion device including a first-conductivity-type crystalline semiconductor region that is provided over a conductive layer and that has an uneven surface by including a plurality of whiskers including an impurity element imparting the first conductivity type; and a second-conductivity-type crystalline semiconductor region that covers the uneven surface of the first-conductivity-type crystalline semiconductor region, in which the second conductivity type is opposite to the first conductivity type.

An embodiment of the present invention is a photoelectric conversion device including a first-conductivity-type crystalline semiconductor region over a conductive layer; and a second-conductivity-type crystalline semiconductor region that is provided over the first-conductivity-type crystalline semiconductor region and has an uneven surface by including a plurality of whiskers including an impurity element imparting the second conductivity type, in which the second conductivity type is opposite to the first conductivity type.

An embodiment of the present invention is a photoelectric conversion device including a first-conductivity-type crystalline semiconductor region and a second-conductivity-type crystalline semiconductor region that are stacked over an electrode, in which the first-conductivity-type crystalline semiconductor region includes a crystalline semiconductor region including an impurity element imparting the first conductivity type; and a plurality of whiskers that is provided over the crystalline semiconductor region and includes a crystalline semiconductor including an impurity element imparting the first conductivity type. Since the first-conductivity-type crystalline semiconductor region includes the plurality of whiskers, a surface of the second-conductivity-type crystalline semiconductor region is uneven. Further, an interface between the first-conductivity-type crystalline semiconductor region and the second-conductivity-type crystalline semiconductor region is uneven.

An embodiment of the present invention is a photoelectric conversion device including a first-conductivity-type crystalline semiconductor region and a second-conductivity-type crystalline semiconductor region that are stacked over an electrode, in which the second-conductivity-type crystalline semiconductor region includes a crystalline semiconductor region including an impurity element imparting the second conductivity type; and a plurality of whiskers that is provided over the crystalline semiconductor region and includes a crystalline semiconductor including an impurity element imparting the second conductivity type. Since the second-conductivity-type crystalline semiconductor region includes the plurality of whiskers, a surface of the second-conductivity-type crystalline semiconductor region is uneven.

Note that in the above photoelectric conversion device, the first-conductivity-type crystalline semiconductor region is one of an n-type semiconductor region and a p-type semiconductor region, and the second-conductivity-type crystalline semiconductor region is the other of the n-type semiconductor region and the p-type semiconductor region.

An embodiment of the present invention is a photoelectric conversion device including, in addition to the above structure, a third-conductivity-type semiconductor region, an intrinsic semiconductor region, and a fourth-conductivity-type semiconductor region which are stacked over the second-conductivity-type crystalline semiconductor region. Accordingly, a surface of the fourth-conductivity-type semiconductor region is uneven.

Note that in the above photoelectric conversion device, each of the first-conductivity-type crystalline semiconductor region and the third-conductivity-type semiconductor region is one of an n-type semiconductor region and a p-type semiconductor region, and each of the second-conductivity-type crystalline semiconductor region and the fourth-conductivity-type semiconductor region is the other of the n-type semiconductor region and the p-type semiconductor region.

Directions of axes of the plurality of whiskers which is provided over the first-conductivity-type crystalline semiconductor region or the second-conductivity-type crystalline semiconductor region may be the normal direction of the electrode. Alternatively, the directions of axes of the plurality of whiskers which is provided over the first-conductivity-type crystalline semiconductor region or the second-conductivity-type crystalline semiconductor region may be varied.

The electrode includes a conductive layer. The conductive layer can be formed using a metal element which forms silicide by reacting with silicon. Alternatively, the conductive layer can be formed with a layered structure of a layer which is formed using a material having high conductivity such as a metal element typified by platinum, aluminum, or copper, and a layer which is formed using a metal element forming silicide by reacting with silicon.

The electrode may include a mixed layer covering the conductive layer. The mixed layer may include silicon and a metal element which forms the conductive layer. In the case where the conductive layer is formed using a metal element which forms silicide by reacting with silicon, the mixed layer may be formed of silicide.

In the photoelectric conversion device, the first-conductivity-type crystalline semiconductor region or the second-conductivity-type crystalline semiconductor region includes a plurality of whiskers, thereby reducing light reflectance. In addition, since the photoelectric conversion layer absorbs light incident on the photoelectric conversion layer owing to a light-trapping effect, characteristics of the photoelectric conversion device can be improved.

An embodiment of the present invention is a method for manufacturing a photoelectric conversion device, including the steps of: over a conductive layer, forming a first-conductivity-type crystalline semiconductor region that includes a crystalline semiconductor region and a plurality of whiskers including a crystalline semiconductor by a low pressure CVD (LPCVD) method using a deposition gas containing silicon and a gas imparting the first conductivity type as source gases; and forming a second-conductivity-type crystalline semiconductor region over the first-conductivity-type crystalline semiconductor region by a low pressure CVD method using a deposition gas containing silicon and a gas imparting the second conductivity type as a source gas.

An embodiment of the present invention is a method for manufacturing a photoelectric conversion device, including the steps of: over a conductive layer, forming a first-conductivity-type crystalline semiconductor region by a low pressure CVD method using a deposition gas containing silicon and a gas imparting the first conductivity type as source gases; and forming, over the first-conductivity-type crystalline semiconductor region, a second-conductivity-type crystalline semiconductor region that includes a crystalline semiconductor region and a plurality of whiskers including a crystalline semiconductor by a low pressure CVD method using a deposition gas containing silicon and a gas imparting the second conductivity type as a source gas.

Note that the low pressure CVD method is performed at a temperature higher than 550° C. In addition, silicon hydride, silicon fluoride, or silicon chloride may be used for the deposition gas containing silicon. In addition, the gas imparting the first conductivity type is one of diborane and phosphine, and the gas imparting the second conductivity type is the other of the diborane and the phosphine.

By a low pressure CVD method, the first-conductivity-type crystalline semiconductor region which includes the plurality of whiskers or the second-conductivity-type crystalline semiconductor region which includes the plurality of whiskers can be formed over the conductive layer which is formed using a metal element forming silicide by reacting with silicon.

Note that in this specification, an “intrinsic semiconductor” refers to not only a so-called intrinsic semiconductor in which the Fermi level lies in the middle of the band gap, but a semiconductor in which the concentration of an impurity imparting p-type or n-type conductivity is 1×10²⁰ cm⁻³ or lower and photoconductivity is 100 times or more as high as the dark conductivity. This intrinsic semiconductor may include an impurity element belonging to Group 13 or Group 15 of the periodic table. Accordingly, the problems can be solved even with the use of the semiconductor having n-type or p-type conductivity instead of using the intrinsic semiconductor. Therefore, another semiconductor having the same effect can be used. Such a substantially intrinsic semiconductor is included in an intrinsic semiconductor in this specification.

According to an embodiment of the present invention, the surface of the second-conductivity-type crystalline semiconductor region is uneven, whereby the characteristics of the photoelectric conversion device can be improved. In other words, by providing a group of whiskers for a plane on a light incident side of the second-conductivity-type crystalline semiconductor region, surface reflection can be reduced.

### BRIEF DESCRIPTION OF THE DRAWINGS

In the accompanying drawings:

FIG. 1 is a top view illustrating a photoelectric conversion device;

FIG. 2 is a cross-sectional view illustrating a photoelectric conversion device;

FIG. 3 is a cross-sectional view illustrating a photoelectric conversion device;

FIGS. 4A to 4C are cross-sectional views illustrating a method for manufacturing a photoelectric conversion device;

FIGS. 5A and 5B are cross-sectional views illustrating a method for manufacturing a photoelectric conversion device; and

FIG. 6 is a cross-sectional view illustrating a photoelectric conversion device.

### DETAILED DESCRIPTION OF THE INVENTION

Hereinafter, embodiments of the present invention will be described with reference to the drawings. Note that the invention is not limited to the following description, and it will be easily understood by those skilled in the art that the mode and detail can be variously changed without departing from the spirit and scope of the invention. Thus, the present invention should not be interpreted as being limited to the following description of the embodiments. In description with reference to the drawings, in some cases, the same reference numerals are used in common for the same portions in different drawings. Further, in some cases, the same hatching patterns are applied to similar parts, and the similar parts are not necessarily designated by reference numerals.

Note that in each drawing described in this specification, the size, the layer thickness, or the region of each component is exaggerated for clarity in some cases. Therefore, embodiments of the present invention are not limited to such scales.

Note that terms such as “first”, “second”, and “third” in this specification are used in order to avoid confusion among components, and the terms do not limit the components numerically. Therefore, for example, the term “first” can be replaced with the term “second”, “third”, or the like as appropriate.

### Embodiment 1

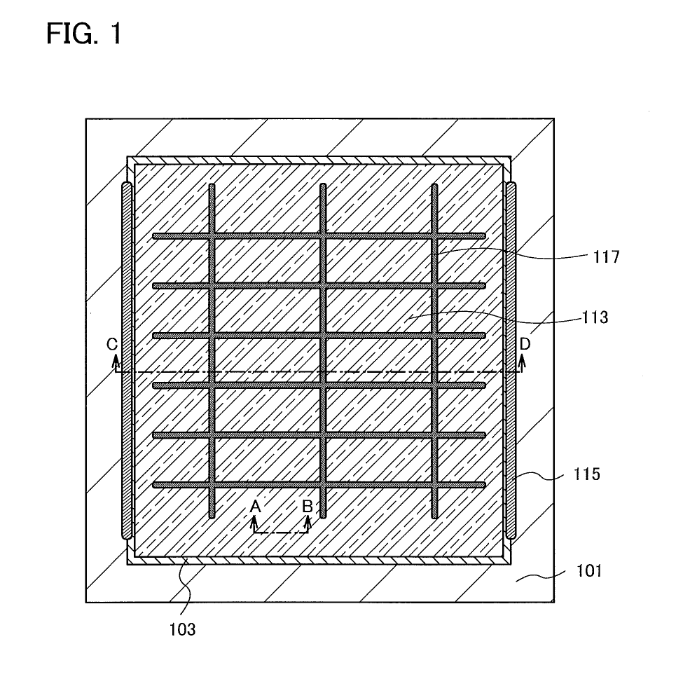

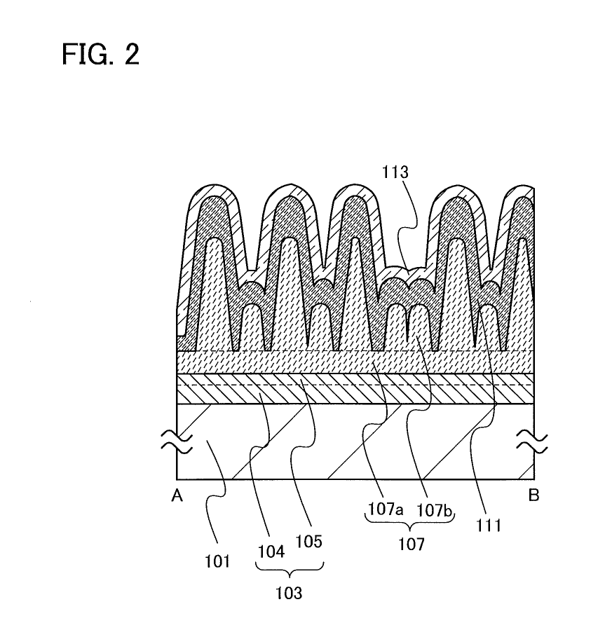

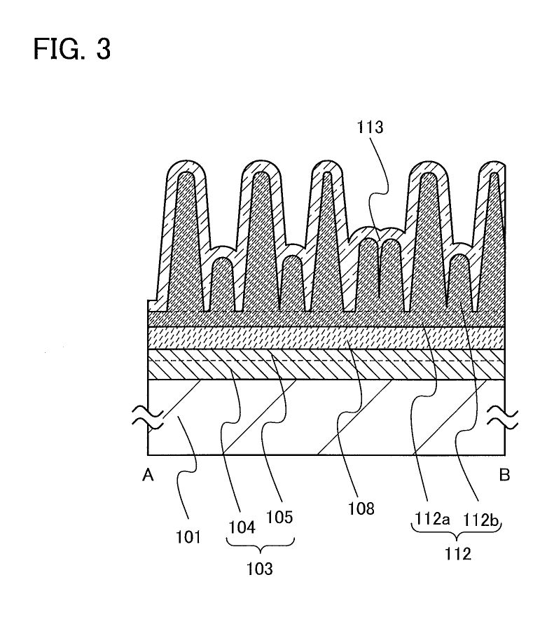

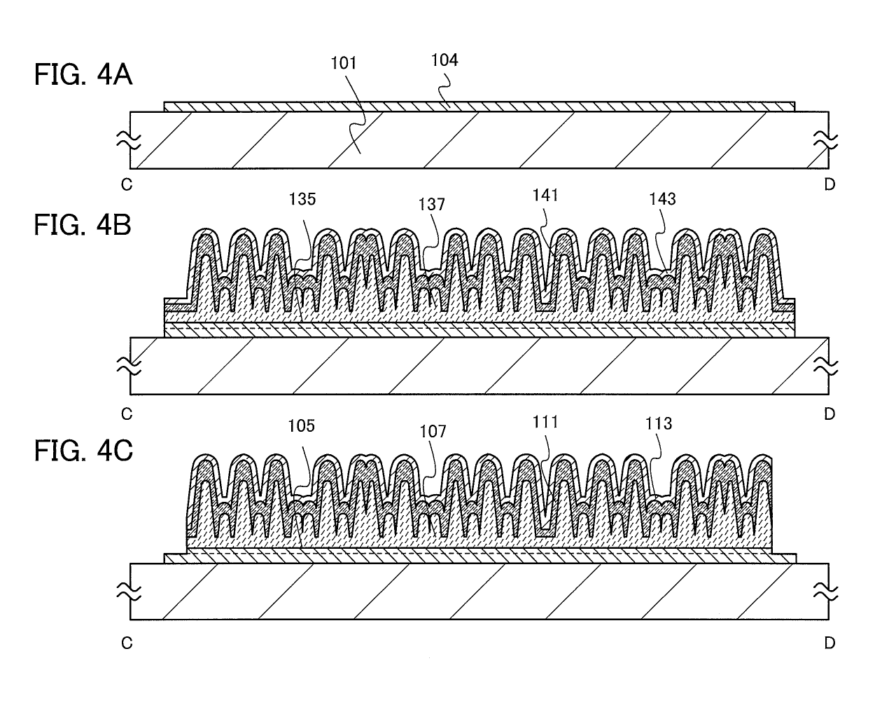

In this embodiment, a structure of a photoelectric conversion device which is an embodiment of the present invention will be described with reference to FIG. 1, FIG. 2, FIG. 3, and FIGS. 4A to 4C.

The photoelectric conversion device described in this embodiment includes a first-conductivity-type crystalline semiconductor region and a second-conductivity-type crystalline semiconductor region. The first-conductivity-type crystalline semiconductor region is provided over a conductive layer and has an uneven surface formed due to a plurality of whiskers which are formed using a crystalline semiconductor including an impurity element imparting first conductivity type. The second-conductivity-type crystalline semiconductor region is provided to cover the uneven surface of the first-conductivity-type crystalline semiconductor region. The second conductivity type is opposite to the first conductivity type.

FIG. 1 is a schematic view of a top surface of a photoelectric conversion device. Although not illustrated, a photoelectric conversion layer is formed over an electrode 103 which is formed over a substrate 101. Further, an auxiliary electrode 115 is formed over the electrode 103 and a grid electrode 117 is formed over a second-conductivity-type crystalline semiconductor region. The auxiliary electrode 115 functions as a terminal for extracting electric energy to the outside. The grid electrode 117 is formed over the second-conductivity-type crystalline semiconductor region to reduce resistance of the second-conductivity-type crystalline semiconductor region. Here, a cross section of a dashed-and-dotted line A-B in FIG. 1 is described with reference to FIG. 2 and FIG. 3.

FIG. 2 is a schematic view of a photoelectric conversion device including the substrate 101, the electrode 103, a first-conductivity-type crystalline semiconductor region 107, a second-conductivity-type crystalline semiconductor region 111, and an insulating layer 113. The second conductivity type is opposite to the first conductivity type. The first-conductivity-type crystalline semiconductor region 107 and the second-conductivity-type crystalline semiconductor region 111 function as a photoelectric conversion layer. The insulating layer 113 is formed over the second-conductivity-type crystalline semiconductor region 111. The first-conductivity-type crystalline semiconductor region 107 has an uneven surface formed due to a plurality of whiskers which are formed using a crystalline semiconductor including an impurity element imparting first-conductivity-type.

In this embodiment, an interface between the electrode 103 and the first-conductivity-type crystalline semiconductor region 107 is flat. The first-conductivity-type crystalline semiconductor region 107 includes a flat portion and a plurality of whiskers (a group of whiskers). Further, an interface between the first-conductivity-type crystalline semiconductor region 107 and the second-conductivity-type crystalline semiconductor region 111 is uneven. That is, a surface of the second-conductivity-type crystalline semiconductor region 111 is uneven.

In this embodiment, a p-type crystalline semiconductor layer and an n-type crystalline semiconductor layer are used as the first-conductivity-type crystalline semiconductor region 107 and the second-conductivity-type crystalline semiconductor region 111, respectively; however, the p-type conductivity and the n-type conductivity may be interchanged with each other.

As the substrate 101, a glass substrate typified by an aluminosilicate glass substrate, a barium borosilicate glass substrate, an aluminoborosilicate glass substrate, a sapphire substrate, and a quartz substrate can be used. Alternatively, a substrate in which an insulating film is formed over a metal substrate such as a stainless steel substrate or the like may be used. In this embodiment, a glass substrate is used as the substrate 101.

Note that the electrode 103 includes only the conductive layer 104 in some cases. Alternatively, the electrode 103 includes the conductive layer 104 and a mixed layer 105 formed at a surface of the conductive layer in some cases. Further alternatively, the electrode 103 includes only the mixed layer 105 in some cases.

The conductive layer 104 is formed using a metal element which forms silicide by reacting with silicon. Alternatively, a stacked layer structure may be used, which includes a layer formed using a metal element having high conductivity typified by platinum, aluminum, copper, titanium, an aluminum alloy to which an element which improves heat resistance, such as silicon, titanium, neodymium, scandium, or molybdenum, is added, or the like on the substrate 101 side; and a layer formed using a metal element which forms silicide by reacting with silicon on the first-conductivity-type crystalline semiconductor region 107 side. Examples of the metal element which forms silicide by reacting with silicon include zirconium, titanium, hafnium, vanadium, niobium, tantalum, chromium, molybdenum, cobalt, nickel, and the like.

The mixed layer 105 may be formed using silicon and the metal element which forms the conductive layer 104. Note that in the case where the mixed layer 105 is formed using silicon and the metal element which forms the conductive layer 104, active species of the source gas are supplied to a deposition portion depending on heating conditions in forming the first-conductivity-type crystalline semiconductor region by an LPCVD method; therefore, silicon is diffused into the conductive layer 104 and thus the mixed layer 105 is formed.

In the case where the conductive layer 104 is formed using a metal element which forms silicide by reacting with silicon, silicide including the metal element is formed in the mixed layer 105; typically, one or more of zirconium silicide, titanium silicide, hafnium silicide, vanadium silicide, niobium silicide, tantalum silicide, chromium silicide, molybdenum silicide, cobalt silicide, and nickel silicide is/are formed. Alternatively, an alloy layer of silicon and a metal element which forms silicide is formed.

In the case where the mixed layer 105 is provided between the conductive layer 104 and the first-conductivity-type crystalline semiconductor region 107, resistance at an interface between the conductive layer 104 and the first-conductivity-type crystalline semiconductor region 107 can be reduced; therefore series resistance can be further reduced as compared to the case where the first-conductivity-type crystalline semiconductor region 107 is directly stacked over the conductive layer 104. In addition, the adhesiveness between the conductive layer 104 and the first-conductivity-type crystalline semiconductor region 107 can be increased. As a result, yield of the photoelectric conversion device can be improved.

Note that the conductive layer 104 may have a foil shape, a plate shape, or a net shape. With such a shape, the conductive layer 104 can hold its shape by itself, and the substrate 101 is therefore not essential. For this reason, cost can be reduced. In addition, in the case where the conductive layer 104 has a foil shape, a flexible photoelectric conversion device can be manufactured.

The first-conductivity-type crystalline semiconductor region 107 is typically formed using a semiconductor to which an impurity element imparting the first conductivity type is added. Silicon is suitable for the semiconductor material, considering productivity, cost, or the like. When silicon is used as the semiconductor material, phosphorus or arsenic, which imparts n-type conductivity, or boron, which imparts p-type conductivity, is used as the impurity element imparting the first conductivity type. Here, the first-conductivity-type crystalline semiconductor region 107 is formed using a p-type crystalline semiconductor.

The first-conductivity-type crystalline semiconductor region 107 includes a crystalline semiconductor region 107a which includes an impurity element imparting the first conductivity type (hereinafter referred to as the crystalline semiconductor region 107a) and a group of whiskers including a plurality of whiskers 107b which is provided over the crystalline semiconductor region 107a and which is formed using a crystalline semiconductor including an impurity element imparting the first conductivity type (hereinafter referred to as the whiskers 107b). Note that the interface between the crystalline semiconductor region 107a and the whiskers 107b is unclear. Therefore, a plane that is in the same level as the bottom of the deepest valley of valleys formed among whiskers 107b and is parallel to a surface of the electrode 103 is regarded as the interface between the crystalline semiconductor region 107a and the whiskers 107b.

The crystalline semiconductor region 107a covers the electrode 103. The whisker 107b is a whisker-like protrusion, and a plurality of protrusions is dispersed. Note that the whisker 107b may have a columnar-like shape such as a cylinder or a prism, or a needle-like shape such as a cone or a pyramid. The top of the whisker 107b may be rounded. The width of the whisker 107b is greater than or equal to 100 run and less than or equal to 10 μm, preferably greater than or equal to 500 nm and less than or equal to 3 μm. Further, the length in the axis of the whisker 107b is greater than or equal to 300 nm and less than or equal to 20 μm, preferably greater than or equal to 500 nm and less than or equal to 15 μm. The photoelectric conversion device in this embodiment includes one or more of the above-described whiskers.

Note that the length in the axis of the whisker 107b is the distance between the top of the whisker 107b and the crystalline semiconductor region 107a in the axis running through the top of the whisker 107b or the center of the top surface of the whisker 107b. The thickness of the first-conductivity-type crystalline semiconductor region 107 is the sum of the thickness of the crystalline semiconductor region 107a and the length of a normal from the top of the whisker 107b to the crystalline semiconductor region 107a (i.e., the height of the whisker). The width of the whisker 107b refers to a length of a longer axis of a transverse cross-sectional shape at the interface between the crystalline semiconductor region 107a and the whisker 107b.

Note that the direction in which the whisker 107b extends from the crystalline semiconductor region 107a is referred to as a longitudinal direction. A cross-sectional shape along the longitudinal direction is referred to as a longitudinal cross-sectional shape. In addition, the shape of a plane in which the longitudinal direction is a normal direction is referred to as a transverse cross-sectional shape.

In FIG. 2, the longitudinal directions of the whiskers 107b included in the first-conductivity-type crystalline semiconductor region 107 are one direction, e.g., the direction normal to the surface of the electrode 103. Note that the longitudinal direction of the whisker 107b may be substantially the same as the direction normal to the surface of the electrode 103. In that case, it is preferable that the difference between the angles of the directions be typically within 5°.

Note that the longitudinal directions of the whiskers 107b included in the first-conductivity-type crystalline semiconductor region 107 are one direction, e.g., the direction normal to the surface of the electrode 103 in FIG. 2; however, the longitudinal directions of the whiskers 107b may be varied. Typically, the first-conductivity-type crystalline semiconductor region 107 may include a whisker whose longitudinal direction is substantially the same as the normal direction and a whisker whose longitudinal direction is different from the normal direction.

The second-conductivity-type crystalline semiconductor region 111 is formed using an n-type crystalline semiconductor. Note that semiconductor materials which can be used for the second-conductivity-type crystalline semiconductor region 111 are the same as those for the first-conductivity-type crystalline semiconductor region 107.

In this embodiment, in the photoelectric conversion layer, an interface between the first-conductivity-type crystalline semiconductor region 107 and the second-conductivity-type crystalline semiconductor region 111 and a surface of the second-conductivity-type crystalline semiconductor region 111 are uneven. Therefore, reflectance of light incident on the insulating layer 113 can be reduced. Further, the light incident on the photoelectric conversion layer is efficiently absorbed by the photoelectric conversion layer due to a light-trapping effect; thus, the characteristics of the photoelectric conversion device can be improved.

Note that an interface between the first-conductivity-type crystalline semiconductor region 108 and the second-conductivity-type crystalline semiconductor region 112 may be flat as illustrated in FIG. 3, whereas the interface between the first-conductivity-type crystalline semiconductor region 107 and the second-conductivity-type crystalline semiconductor region 111 is uneven as illustrated in FIG. 2. The second-conductivity-type crystalline semiconductor region 112 has an uneven surface formed due to a plurality of whiskers which are formed using a crystalline semiconductor including an impurity element imparting second conductivity type.

The second-conductivity-type crystalline semiconductor region 112 illustrated in FIG. 3 includes a crystalline semiconductor region 112a including an impurity element imparting the second conductivity type (hereinafter referred to as a crystalline semiconductor region 112a) and a group of whiskers including plural whiskers 112b which is provided over the crystalline semiconductor region 112a and formed using a crystalline semiconductor including an impurity element imparting the second conductivity type (hereinafter referred to as the whiskers 112b). Note that the interface between the crystalline semiconductor region 112a and the whiskers 112b is unclear. Therefore, a plane that is in the same level as the bottom of the deepest valley of valleys formed among whiskers 112b and is parallel to a surface of the electrode 103 is regarded as the interface between the crystalline semiconductor region 112a and the whiskers 112b.

The whisker 112b is a whisker-like protrusion, and a plurality of protrusions is dispersed. Note that the whisker 112b may have a columnar-like shape such as a cylinder or a prism, or a needle-like shape such as a cone or a pyramid. The top of the whisker 112b may be rounded.

The longitudinal directions of the whiskers 112b included in the second-conductivity-type crystalline semiconductor region 112 are one direction, e.g., the direction normal to the surface of the electrode 103. Note that the longitudinal direction of the whisker 112b may be substantially, the same as the direction normal to the surface of the electrode 103. In that case, it is preferable that the difference between the angles of the directions be typically within 5°.

Note that the longitudinal directions of the whiskers 112b included in the second-conductivity-type crystalline semiconductor region 112 are one direction, e.g., the direction normal to the surface of the electrode 103 in FIG. 3; however, the longitudinal directions of the whiskers 112b may be varied. Typically, the second-conductivity-type crystalline semiconductor region 112 may include a whisker whose longitudinal direction is substantially the same as the normal direction and a whisker whose longitudinal direction is different from the normal direction.

In the photoelectric conversion layer of the photoelectric conversion device illustrated in FIG. 3, a surface of the second-conductivity-type crystalline semiconductor region 112 is uneven. Therefore, reflectance of light incident on the insulating layer 113 can be reduced. Further, the light incident on the photoelectric conversion layer is efficiently absorbed by the photoelectric conversion layer due to a light-trapping effect; thus, the characteristics of the photoelectric conversion device can be improved.

The auxiliary electrode 115 and the grid electrode 117 illustrated in FIG. 1 are formed of a layer formed using a metal element such as silver, copper, aluminum, palladium, lead, or tin. The grid electrode 117 is formed to be in contact with the second-conductivity-type crystalline semiconductor region, whereby the resistance loss of the second-conductivity-type crystalline semiconductor region can be reduced, and especially, the electrical characteristics under high illuminance can be enhanced. The grid electrode 117 has a grid pattern (or a comb-like pattern, a comb-like shape, or a comb-tooth-like pattern) in order to increase a light-receiving area of the photoelectric conversion layer.

Note that the insulating layer 113 which has an anti-reflection function is preferably formed over exposed surfaces of the electrode 103 and the second-conductivity-type crystalline semiconductor region. For the insulating layer 113, a material whose refractive index is between the refractive indices of the second-conductivity-type crystalline semiconductor region and air is used. In addition, a material which transmits light with a predetermined wavelength is used so that incidence of light on the second-conductivity-type crystalline semiconductor region is not interrupted. The use of such a material can prevent reflection at the light incidence plane of the second-conductivity-type crystalline semiconductor region. Note that as such a material, silicon nitride, silicon nitride oxide, or magnesium fluoride can be given, for example.

Although not illustrated, an electrode may be provided over the second-conductivity-type crystalline semiconductor region. The electrode is formed using a light-transmitting conductive layer of an alloy of indium oxide and tin oxide (ITO), zinc oxide (ZnO), tin oxide (SnO₂), zinc oxide containing aluminum, or the like.

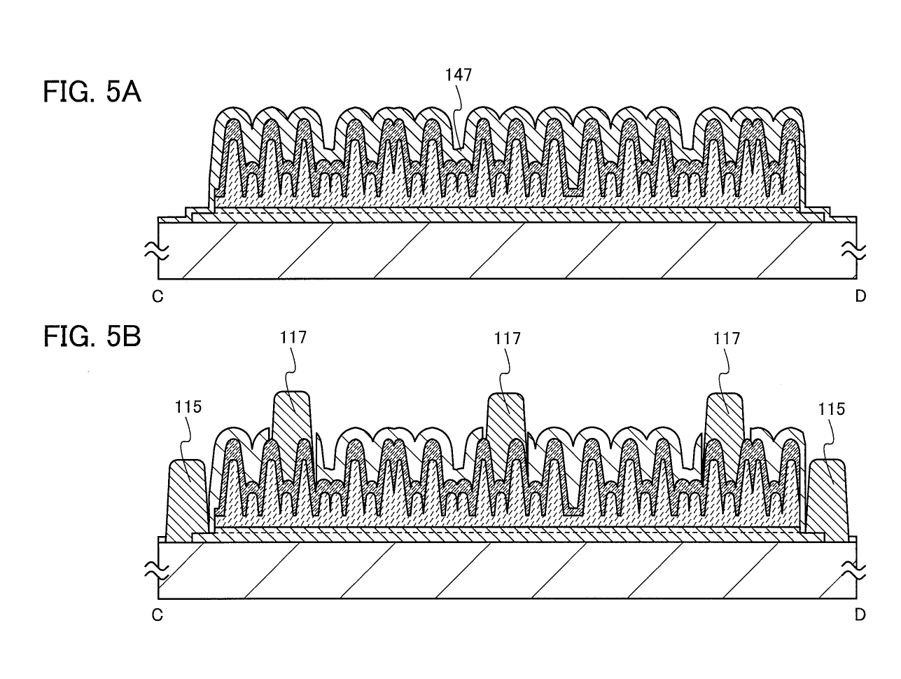

Next, a method for manufacturing the photoelectric conversion device illustrated in FIG. 1 and FIG. 2 will be described with reference to FIGS. 4A to 4C and FIGS. 5A and 5B. Here, a cross section taken along a dashed-and-dotted line C-D in FIG. 1 will be described with reference to FIGS. 4A to 4C and FIGS. 5A and 5B.

As in FIG. 4A, the conductive layer 104 is formed over the substrate 101. The conductive layer 104 can be formed by a printing method, a sol-gel method, a coating method, an ink-jet method, a CVD method, a sputtering method, an evaporation method, or the like, as appropriate. Note that, in the case where the conductive layer 104 has a foil shape, it is not necessary to provide the substrate 101. Further, roll-to-roll processing can be employed.

Next, as in FIG. 4B, a first-conductivity-type crystalline semiconductor region 137 and a second-conductivity-type crystalline semiconductor region 141 are formed by an LPCVD method. Note that a light-transmitting conductive layer may be formed over the second-conductivity-type crystalline semiconductor region 141.

The LPCVD method is performed as follows: heating is performed at temperature higher than 550° C. and in the range of temperature at which an LPCVD apparatus and the conductive layer 104 can withstand, preferably higher than or equal to 580° C. and lower than 650° C.; at least a deposition gas containing silicon is used as a source gas; and the pressure in a reaction chamber of the LPCVD apparatus is set to higher than or equal to a lower limit at which the pressure can be maintained while the source gas flows and lower than or equal to 200 Pa. Examples of the deposition gas containing silicon include silicon hydride, silicon fluoride, and silicon chloride; typically, SiH₄, Si₂H₆, SiF₄, SiCl₄, Si₂Cl₆, and the like are given. Note that hydrogen may be introduced into the source gas.

When the first-conductivity-type crystalline semiconductor region 137 is formed by the LPCVD method, a mixed layer 135 is formed between the conductive layer 104 and the first-conductivity-type crystalline semiconductor region 137 depending on heating conditions. In a step of forming the first-conductivity-type crystalline semiconductor region 137, active species of the source gas are constantly supplied to the crystalline semiconductor region 137 that is being deposited, and silicon diffuses from the first-conductivity-type crystalline semiconductor region 137 to the conductive layer 104, so that the mixed layer 135 is formed. For this reason, a low-density region (a sparse region) is not easily formed at an interface between the conductive layer 104 and the first-conductivity-type crystalline semiconductor region 137, and thus the characteristics of the interface between the conductive layer 104 and the first-conductivity-type crystalline semiconductor region 137 are improved, so that series resistance can be reduced.

The first-conductivity-type crystalline semiconductor region 137 is formed by an LPCVD method in which diborane and a deposition gas containing silicon are introduced into the reaction chamber of the LPCVD apparatus as a source gas. The thickness of the first-conductivity-type crystalline semiconductor region 137 is greater than or equal to 500 nm and less than or equal to 20 μm. Here, a crystalline silicon layer to which boron is added is formed for the first-conductivity-type crystalline semiconductor region 137.

The introduction of diborane into the reaction chamber of the LPCVD apparatus is stopped. Then, the second-conductivity-type crystalline semiconductor region 141 is formed by an LPCVD method in which phosphine or arsine and a deposition gas containing silicon are introduced into the reaction chamber of the LPCVD apparatus as a source gas. The thickness of the second-conductivity-type crystalline semiconductor region 141 is greater than or equal to 5 nm and less than or equal to 500 nm. Here, a crystalline silicon layer to which phosphorus or arsenic is added is formed for the second-conductivity-type crystalline semiconductor region 141.

Through the above steps, the photoelectric conversion layer including the first-conductivity-type crystalline semiconductor region 137 and the second-conductivity-type crystalline semiconductor region 141 can be formed.

Note that, in the manufacturing process of the photoelectric conversion device illustrated in FIG. 1, in the case where the introduction of diborane into the reaction chamber of the LPCVD apparatus is stopped after whiskers are formed in the first-conductivity-type crystalline semiconductor region 107, the interface between the first-conductivity-type crystalline semiconductor region 137 and the second-conductivity-type crystalline semiconductor region 141 is uneven as in FIG. 4B. On the other hand, in the case where the introduction of diborane into the reaction chamber of the LPCVD apparatus is stopped before whiskers are formed in the first-conductivity-type crystalline semiconductor region, the interface between the first-conductivity-type crystalline semiconductor region 108 and the second-conductivity-type crystalline semiconductor region 112 is flat as in FIG. 3.

A surface of the conductive layer 104 may be cleaned with hydrofluoric acid before the formation of the first-conductivity-type crystalline semiconductor region 137. This step can enhance the adhesiveness between the electrode 103 and the first-conductivity-type crystalline semiconductor region 137.

Further, nitrogen or a rare gas such as helium, neon, argon, or xenon may be added to the source gas of the first-conductivity-type crystalline semiconductor region 137 and the source gas of the second-conductivity-type crystalline semiconductor region 141. In the case where a rare gas or nitrogen is added to the source gas of the first-conductivity-type crystalline semiconductor region 137 and the source gas of the second-conductivity-type crystalline semiconductor region 141, the density of whiskers can be increased.

After the formation of the first-conductivity-type crystalline semiconductor region 137 or the formation of the second-conductivity-type crystalline semiconductor region 141, in the case where introduction of the source gas into the reaction chamber of the LPCVD apparatus is stopped and the temperature is maintained in a vacuum state (i.e., vacuum heating), the density of whiskers included in the first-conductivity-type crystalline semiconductor region 137 or the second-conductivity-type crystalline semiconductor region 141 can be increased.

Next, a mask is formed over the second-conductivity-type crystalline semiconductor region 141, and then the mixed layer 135, the first-conductivity-type crystalline semiconductor region 137, and the second-conductivity-type crystalline semiconductor region 141 are etched with use of the mask. As a result, the conductive layer 104 is partly exposed, and the mixed layer 105, the first-conductivity-type crystalline semiconductor region 107, and the second-conductivity-type crystalline semiconductor region 111 can be formed as in FIG. 4C. Note that, although the mixed layer 135 is partly etched here, the mixed layer 135 may be partly exposed without being etched.

Then, as in FIG. 5A, an insulating layer 147 is formed over the substrate 101, the conductive layer 104, the first-conductivity-type crystalline semiconductor region 107, and the second-conductivity-type crystalline semiconductor region 111. The insulating layer 147 can be formed by a CVD method, a sputtering method, an evaporation method, or the like.

After that, the insulating layer 147 is partly etched so that part of the conductive layer 104 and part of the second-conductivity-type crystalline semiconductor region 111 are exposed. Next, as in FIG. 5B, the auxiliary electrode 115 connected to the conductive layer 104 is formed in an exposed portion of the conductive layer 104, and the grid electrode 117 connected to the second-conductivity-type crystalline semiconductor region 111 is formed in an exposed portion of the second-conductivity-type crystalline semiconductor region 111. The auxiliary electrode 115 and the grid electrode 117 can be formed by a printing method, a sol-gel method, a coating method, an ink-jet method, or the like.

Through the above steps, a photoelectric conversion device with high conversion efficiency can be manufactured without forming an electrode with a texture structure.

### Embodiment 2

In this embodiment, a method for manufacturing a photoelectric conversion layer which has fewer defects than the photoelectric conversion layer in Embodiment 1 will be described.

After one or more of the first-conductivity-type crystalline semiconductor region 107, the first-conductivity-type crystalline semiconductor region 108, the second-conductivity-type crystalline semiconductor region 111, and the second-conductivity-type crystalline semiconductor region 112, which are described in Embodiment 1, are formed, the temperature of a reaction chamber in an LPCVD apparatus is set at higher than or equal to 400° C. and lower than or equal to 450° C., introduction of a source gas into the LPCVD apparatus is stopped, and hydrogen is introduced. Then, in a hydrogen atmosphere, heat treatment at a temperature higher than or equal to 400° C. and lower than or equal to 450° C. is performed. In this manner, dangling bonds in one or more of the first-conductivity-type crystalline semiconductor region 107, the first-conductivity-type crystalline semiconductor region 108, the second-conductivity-type crystalline semiconductor region 111, and the second-conductivity-type crystalline semiconductor region 112 can be terminated with hydrogen. The heat treatment is also referred to as hydrogenation treatment. As a result of the heat treatment, defects in one or more of the first-conductivity-type crystalline semiconductor region 107, the first-conductivity-type crystalline semiconductor region 108, the second-conductivity-type crystalline semiconductor region 111, and the second-conductivity-type crystalline semiconductor region 112 can be reduced, which leads to less recombination of photoexcited carriers in defects and also leads to an increase in conversion efficiency of the photoelectric conversion device.

### Embodiment 3

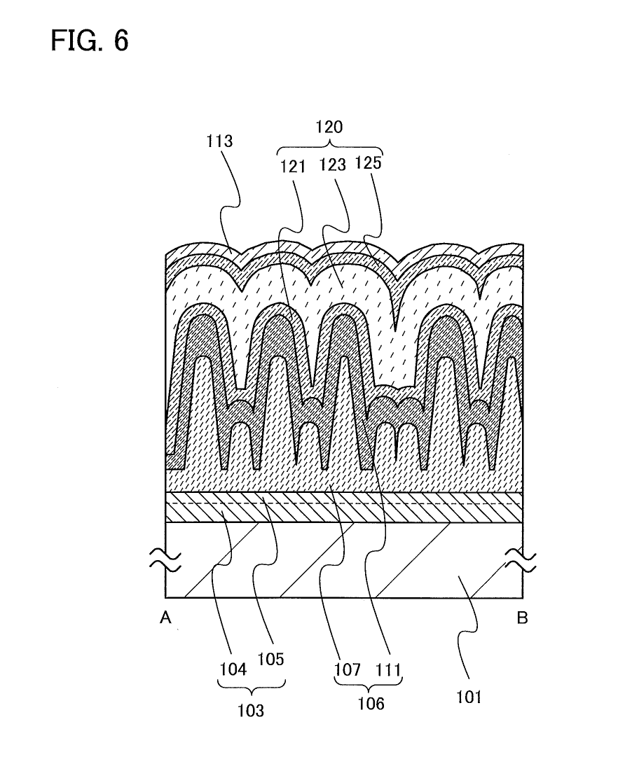

In this embodiment, a structure of a so-called tandem photoelectric conversion device in which a plurality of photoelectric conversion layers is stacked will be described with reference to FIG. 6. Although two photoelectric conversion layers are stacked in this embodiment, three or more photoelectric conversion layers may be stacked. In the following description, the photoelectric conversion layer which is closest to the light incident surface may be referred to as a top cell and the photoelectric conversion layer which is farthest from the light incident surface may be referred to as a bottom cell.

FIG. 6 illustrates a photoelectric conversion device in which the substrate 101, the electrode 103, the photoelectric conversion layer 106 which is the bottom cell, a photoelectric conversion layer 120 which is the top cell, and the insulating layer 113 are stacked. Here, the photoelectric conversion layer 106 includes the first-conductivity-type crystalline semiconductor region 107 and the second-conductivity-type crystalline semiconductor region 111, which are described in Embodiment 1. The photoelectric conversion layer 120 includes a third-conductivity-type semiconductor region 121, an intrinsic semiconductor region 123, and a fourth-conductivity-type semiconductor region 125. The band gap of the photoelectric conversion layer 106 is preferably different from that of the photoelectric conversion layer 120. Use of semiconductors having different band gaps makes it possible to absorb a wide wavelength range of light; thus, a photoelectric conversion efficiency can be improved.

For example, a semiconductor with a large band gap can be used for the top cell while a semiconductor with a small band gap can be used for the bottom cell, and needless to say, vice versa. Here, as an example, a structure where a crystalline semiconductor (typically, crystalline silicon) is used in the photoelectric conversion layer 106, which is the bottom cell, and an amorphous semiconductor (typically, amorphous silicon) is used in the photoelectric conversion layer 120, which is the top cell, is described.

Note that although a structure where light is incident on the insulating layer 113 is described in this embodiment, an embodiment of the disclosed invention is not limited thereto. Light may be incident on the rear surface of the substrate 101 (the lower surface in the drawing).

The structures of the substrate 101, the electrode 103, the photoelectric conversion layer 106, and the insulating layer 113 are similar to those in the above embodiments and description thereof is omitted here.

In the photoelectric conversion layer 120, which is the top cell, a semiconductor layer including a semiconductor material to which an impurity element imparting a conductivity type is added is typically used as the third-conductivity-type semiconductor region 121 and the fourth-conductivity-type semiconductor region 125. Details of the semiconductor material and the like are similar to those of the first-conductivity-type crystalline semiconductor region 107 in Embodiment 1. In this embodiment, the case where silicon is used as the semiconductor material, the third conductivity type is p-type, and the fourth conductivity type is n-type is described. In addition, the crystallinity of the semiconductor layer is amorphous. It is needless to say that the third conductivity type may be n-type, the fourth conductivity type may be p-type, and the semiconductor layer is not necessarily amorphous.

For the intrinsic semiconductor region 123, silicon, silicon carbide, germanium, gallium arsenide, indium phosphide, zinc selenide, gallium nitride, silicon germanium, or the like is used. Alternatively, a semiconductor material including an organic material, a metal oxide semiconductor material, or the like can be used.

In this embodiment, amorphous silicon is used for the intrinsic semiconductor region 123. The thickness of the intrinsic semiconductor region 123 is greater than or equal to 50 nm and less than or equal to 1000 nm, preferably greater than or equal to 100 nm and less than or equal to 450 nm. Needless to say, a semiconductor material other than silicon may be used.

A plasma CVD method, an LPCVD method, or the like may be employed for forming the third-conductivity-type semiconductor region 121, the intrinsic semiconductor region 123, and the fourth-conductivity-type semiconductor region 125. In the case of a plasma CVD method, the intrinsic semiconductor region 123 can be formed in such a manner that the pressure in a reaction chamber of a plasma CVD apparatus is typically greater than or equal to 10 Pa and less than or equal to 1332 Pa, hydrogen and a deposition gas containing silicon are introduced as a source gas to the reaction chamber, and high-frequency electric power is supplied to an electrode to cause glow discharge. The third-conductivity-type semiconductor region 121 can be formed using the above source gas to which diborane is added. The third-conductivity-type semiconductor region 121 is formed with a thickness of greater than or equal to 1 nm and less than or equal to 100 nm, preferably greater than or equal to 5 nm and less than or equal to 50 nm. The fourth-conductivity-type semiconductor region 125 can be formed using the above source gas to which phosphine or arsine is added. The fourth-conductivity-type semiconductor region 125 is formed with a thickness of greater than or equal to 1 nm and less than or equal to 100 nm, preferably greater than or equal to 5 nm and less than or equal to 50 nm.

Alternatively, the third-conductivity-type semiconductor region 121 may be formed by forming an amorphous silicon layer by a plasma CVD method or an LPCVD method without adding an impurity element imparting a conductivity type and then adding boron by a method such as ion injection. The fourth-conductivity-type semiconductor region 125 may be formed by forming an amorphous silicon layer by a plasma CVD method or an LPCVD method without adding an impurity element imparting a conductivity type and then adding phosphorus or arsenic by a method such as ion injection.

As described above, by using amorphous silicon for the photoelectric conversion layer 120, light having a wavelength of less than 800 nm can be effectively absorbed and subjected to photoelectric conversion. Further, by using crystalline silicon for the photoelectric conversion layer 106, light having a longer wavelength (e.g., a wavelength up to approximately 1200 nm) can be absorbed and subjected to photoelectric conversion. Such a structure (a so-called tandem structure) in which photoelectric conversion layers having different band gaps are stacked can significantly increase a photoelectric conversion efficiency.

Note that although amorphous silicon having a large band gap is used in the top cell and crystalline silicon having a small band gap is used in the bottom cell in this embodiment, an embodiment of the disclosed invention is not limited thereto. The semiconductor materials having different band gaps can be used in appropriate combination to form the top cell and the bottom cell. The structure of the top cell and the structure of the bottom cell can be replaced with each other to form the photoelectric conversion device. Alternatively, a stacked structure in which three or more photoelectric conversion layers are stacked can be employed.

With the above structure, the conversion efficiency of a photoelectric conversion device can be increased.

This application is based on Japanese Patent Application serial no. 2010-139999 filed with Japan Patent Office on Jun. 18, 2010, the entire contents of which are hereby incorporated by reference.

What is claimed is:

1. A photoelectric conversion device comprising:
a conductive layer;
a first-conductivity-type crystalline semiconductor region over the conductive layer; and
a second-conductivity-type crystalline semiconductor region over the first-conductivity-type crystalline semiconductor region,
wherein the first-conductivity-type crystalline semiconductor region comprises a plurality of whiskers,
wherein the plurality of whiskers include an impurity element which imparts the first conductivity type,
wherein the first-conductivity-type crystalline semiconductor region has an uneven surface due to the plurality of whiskers, and
wherein the second conductivity type is opposite to the first conductivity type.

2. The photoelectric conversion device according to claim 1, wherein directions of axes of the whiskers are varied.

3. The photoelectric conversion device according to claim 1, wherein directions of axes of the whiskers are a normal direction of the conductive layer.

4. The photoelectric conversion device according to claim 1,
wherein the first-conductivity-type crystalline semiconductor region is one of an n-type semiconductor region and a p-type semiconductor region, and
wherein the second-conductivity-type crystalline semiconductor region is the other of the n-type semiconductor region and the p-type semiconductor region.

5. A photoelectric conversion device comprising:
a conductive layer;
a first-conductivity-type crystalline semiconductor region over the conductive layer;
a second-conductivity-type crystalline semiconductor region over the first-conductivity-type crystalline semiconductor region,
wherein the second-conductivity-type crystalline semiconductor region comprises a plurality of whiskers,
wherein the plurality of whiskers include an impurity element which imparts the second conductivity type,
wherein the second-conductivity-type crystalline semiconductor region has an uneven surface due to the plurality of whiskers, and
wherein the second conductivity type is opposite to the first conductivity type.

6. The photoelectric conversion device according to claim 5, wherein directions of axes of the whiskers are varied.

7. The photoelectric conversion device according to claim 5, wherein directions of axes of the whiskers are a normal direction of the conductive layer.

8. The photoelectric conversion device according to claim 5,
wherein the first-conductivity-type crystalline semiconductor region is one of an n-type semiconductor region and a p-type semiconductor region, and
wherein the second-conductivity-type crystalline semiconductor region is the other of the n-type semiconductor region and the p-type semiconductor region.

9. A photoelectric conversion device comprising:
an electrode; and
a first-conductivity-type crystalline semiconductor region and a second-conductivity-type crystalline semiconductor region stacked over the electrode,
wherein the first-conductivity-type crystalline semiconductor region comprises:
a crystalline semiconductor region including an impurity element imparting the first conductivity type; and
a plurality of whiskers provided over the crystalline semiconductor region, and including a crystalline semiconductor, and
wherein the crystalline semiconductor includes an impurity element imparting the first conductivity type.

10. The photoelectric conversion device according to claim 9, wherein a surface of the first-conductivity-type crystalline semiconductor region is uneven.

11. The photoelectric conversion device according to claim 9, wherein a surface of the second-conductivity-type crystalline semiconductor region is uneven.

12. The photoelectric conversion device according to claim 9, wherein an interface between the first-conductivity-type crystalline semiconductor region and the second-conductivity-type crystalline semiconductor region is uneven.

13. The photoelectric conversion device according to claim 9, wherein directions of axes of the whiskers are varied.

14. The photoelectric conversion device according to claim 9, wherein directions of axes of the whiskers are a normal direction of the electrode.

15. The photoelectric conversion device according to claim 9,
wherein the first-conductivity-type crystalline semiconductor region is one of an n-type semiconductor region and a p-type semiconductor region, and
wherein the second-conductivity-type crystalline semiconductor region is the other of the n-type semiconductor region and the p-type semiconductor region.

16. A photoelectric conversion device comprising:
an electrode;
a first-conductivity-type crystalline semiconductor region, a second-conductivity-type crystalline semiconductor region, a third-conductivity-type semiconductor region, an intrinsic semiconductor region, and a fourth-conductivity-type semiconductor region stacked over the electrode,
wherein the first-conductivity-type crystalline semiconductor region comprises:
a crystalline semiconductor region; and
a plurality of whiskers provided over the crystalline semiconductor region, and including a crystalline semiconductor, and
wherein a surface of the fourth-conductivity-type semiconductor region is uneven.

17. The photoelectric conversion device according to claim 16, wherein a surface of the first-conductivity-type crystalline semiconductor region is uneven.

18. The photoelectric conversion device according to claim 16, wherein a surface of the second-conductivity-type crystalline semiconductor region is uneven.

19. The photoelectric conversion device according to claim 16, wherein an interface between the first-conductivity-type crystalline semiconductor region and the second-conductivity-type crystalline semiconductor region is uneven.

20. The photoelectric conversion device according to claim 16, wherein directions of axes of the whiskers are varied.

21. The photoelectric conversion device according to claim 16, wherein directions of axes of the whiskers are a normal direction of the electrode.

22. The photoelectric conversion device according to any one of claims 16,
wherein each of the first-conductivity-type crystalline semiconductor region and the third-conductivity-type semiconductor region is one of an n-type semiconductor region and a p-type semiconductor region, and
wherein each of the second-conductivity-type crystalline semiconductor region and the fourth-conductivity-type semiconductor region is the other of the n-type semiconductor region and the p-type semiconductor region.

23. The photoelectric conversion device according to claim 16,
wherein the crystalline semiconductor region includes an impurity element imparting the first conductivity type, and
wherein the crystalline semiconductor includes an impurity element imparting the first conductivity type.

24. A method for manufacturing a photoelectric conversion device, comprising the steps of:
forming a first-conductivity-type crystalline semiconductor region over a conductive layer by a low pressure CVD method using a deposition gas containing silicon and a gas imparting the first conductivity type as source gases; and
forming a second-conductivity-type crystalline semiconductor region over the first-conductivity-type crystalline semiconductor region by a low pressure CVD method using a deposition gas containing silicon and a gas imparting the second conductivity type as source gases.

25. The method for manufacturing a photoelectric conversion device, according to claim 24,
wherein the first-conductivity-type crystalline semiconductor region includes a crystalline semiconductor region and a plurality of whiskers including a crystalline semiconductor.

26. The method for manufacturing a photoelectric conversion device, according to claim 24,
wherein the second-conductivity-type crystalline semiconductor region includes a crystalline semiconductor region and a plurality of whiskers including a crystalline semiconductor.

27. The method for manufacturing a photoelectric conversion device, according to claim 24, wherein the low pressure CVD method is performed at a temperature higher than 550° C.

28. The method for manufacturing a photoelectric conversion device, according to claim 24, wherein silicon hydride, silicon fluoride, or silicon chloride is used for the deposition gas containing silicon.

29. The method for manufacturing a photoelectric conversion device, according to claim 24,
wherein the first-conductivity-type crystalline semiconductor region is one of an n-type semiconductor region and a p-type semiconductor region, and
wherein the second-conductivity-type crystalline semiconductor region is the other of the n-type semiconductor region and the p-type semiconductor region.

30. The method for manufacturing a photoelectric conversion device, according to claim 24,
wherein the gas imparting the first conductivity type is one of diborane and phosphine, and
wherein the gas imparting the second conductivity type is the other of the diborane and the phosphine.
